(19) United States
(12) Patent Application Publication
(10) Pub. No.: US 2013/0256359 A1
(43) Pub. Date: Oct. 3, 2013

(54) METHOD FOR CUTTING TRANSMISSION ELECTRON MICROSCOPE MICRO-GRIDS

(71) Applicants: TSINGHUA UNIVERSITY, Beijing (CN); HON HAI PRECISION INDUSTRY CO., LTD., New Taipei (TW)

(72) Inventors: CHEN FENG, Beijing (CN); XUE-WEI GUO, Beijing (CN)

(73) Assignees: HON HAI PRECISION INDUSTRY CO., LTD., New Taipei (TW); TSINGHUA UNIVERSITY, Beijing (CN)

(21) Appl. No.: 13/729,433

(22) Filed: Dec. 28, 2012

(30) Foreign Application Priority Data
Apr. 3, 2012 (CN) 201210095722.0

(51) Int. Cl. B81C 1/00

(52) U.S. Cl. CPC B81C 1/00634
USPC 225/1

(57) ABSTRACT

A method for cutting micro-grids from a metal substrate is provided. First, a metal substrate with a plurality of micro-grids formed on the metal substrate is provided. A cutting apparatus is provided. The cutting module includes a support, a cutting module and a catching module. The metal substrate is laid on the support. Then cutting module is moved above the support to make one of the plurality of micro-grid be located between the support and the cutting module. The cutting module is pressed towards the support to cut the micro-grid off the metal substrate. Then, the micro-grid is caught by the catching module.

### RELATED APPLICATIONS

This application claims all benefits accruing under 35 U.S.C. §119 from China Patent Application No. 201210095722.0, filed on Apr. 3, 2012, in the China Intellectual Property Office, the disclosure of which is incorporated herein by reference. The application is also related to copending applications entitled, “APPARATUS FOR CUTTING TRANSMISSION ELECTRON MICROSCOPE MICRO-GRID”, filed ______ (Atty. Docket No. US45405).

### BACKGROUND

1. Technical Field

The present disclosure relates to a method for cutting transmission electron microscope micro-grids.

2. Description of Related Art

In a transmission electron microscope, a porous micro-grid is used to carry powder samples to observe high resolution transmission electron microscopy (TEM) images. With the development of nanotechnology, applications of micro-grids become increasingly widespread in the field of electron microscopy. A conventional micro-grid has a round structure with a diameter about 3 millimeters. A plurality of micro-grids is formed on a metal substrate simultaneously. When the micro-grid is used, it should be separated from the metal substrate. Because the micro-grid has a small size, it may be difficult to separate the micro-grid from the metal substrate without causing damages to the micro-grid.

What is needed, therefore, is to provide a method for cutting micro-grids from metal substrate.

### BRIEF DESCRIPTION OF THE DRAWING

Many aspects of the present disclosure can be better understood with reference to the following drawings. The components in the drawings are not necessarily to scale, the emphasis instead being placed upon clearly illustrating the principles of the present embodiments.

FIG. 1 is schematic view of a plurality of micro-grids formed on a metal substrate.

FIG. 2 is a schematic view of an embodiment of a cutting apparatus for cutting micro-grids.

FIG. 3 is an exploded schematic view of a support used in the cutting apparatus in FIG. 2.

FIG. 4 is an exploded schematic view of a cutting module in the cutting apparatus in FIG. 2.

FIG. 5 is a cross sectional view of the cutting module in FIG. 4.

FIG. 6 is a schematic view showing the cutting apparatus cutting micro-grids.

FIG. 7 is a cross sectional view of FIG. 6 along line VII-VII.

The disclosure is illustrated by way of example and not by way of limitation in the figures of the accompanying drawings in which like references indicate similar elements. It should be noted that references to “another,” “an,” or “one” embodiment in this disclosure are not necessarily to the same embodiment, and such references mean at least one.

A method for cutting micro-grids from a metal substrate is provided according to one embodiment. The method includes the following steps:

S1: providing a metal substrate with a plurality of micro-grids formed on the metal substrate;

S2: providing a cutting apparatus including a support, a cutting module and a catching module;

S3: laying the metal substrate on the support, moving the cutting module above the metal substrate to make one micro-grid between the support and the cutting module; and

S4: moving the cutting module towards the support to cut the micro-grid off the metal substrate, and catching the micro-grid with the catching module.

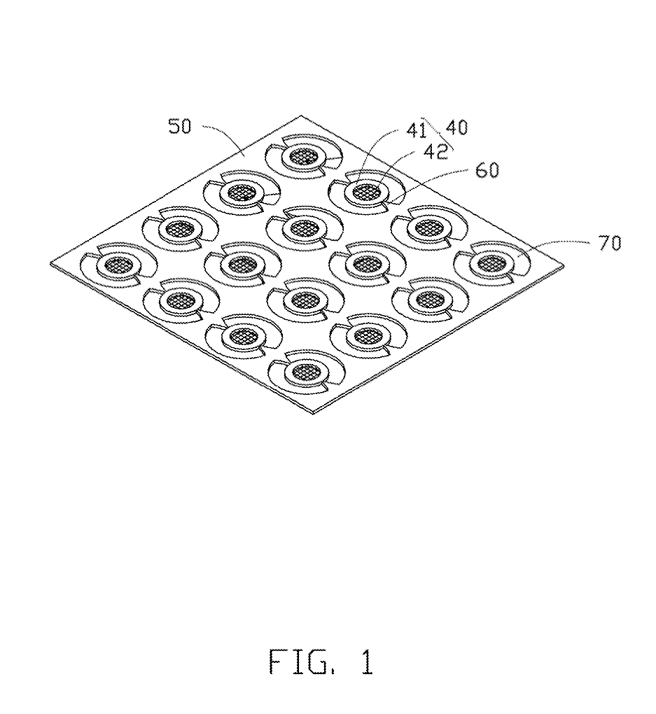

In step S1, referring to FIG. 1, a plurality of micro-grids 40 are formed on a metal substrate 50. The metal substrate 50 defines a plurality of holes 70. The micro-grids 40 and the plurality of holes 70 are arranged in a one by one manner. Each of the micro-grids 40 is suspended in one hole and connected with the metal substrate 50 via two connections 60. Each of the two connections 60 connects with each of the micro-grids 40 via a point contact, and with the metal substrate 50 via a linear contact. In the embodiment according to FIG. 1, each of the connections 60 has a triangular structure. One corner of each of the connections 60 is connected with the micro-grid, and a side of each of the connections 60 opposite with the corner is connected with the metal substrate 50. Each of the micro-grids 40 includes a bridge ring 41 and a grid structure 42. The grid structure 42 is located in the bridge ring 41.

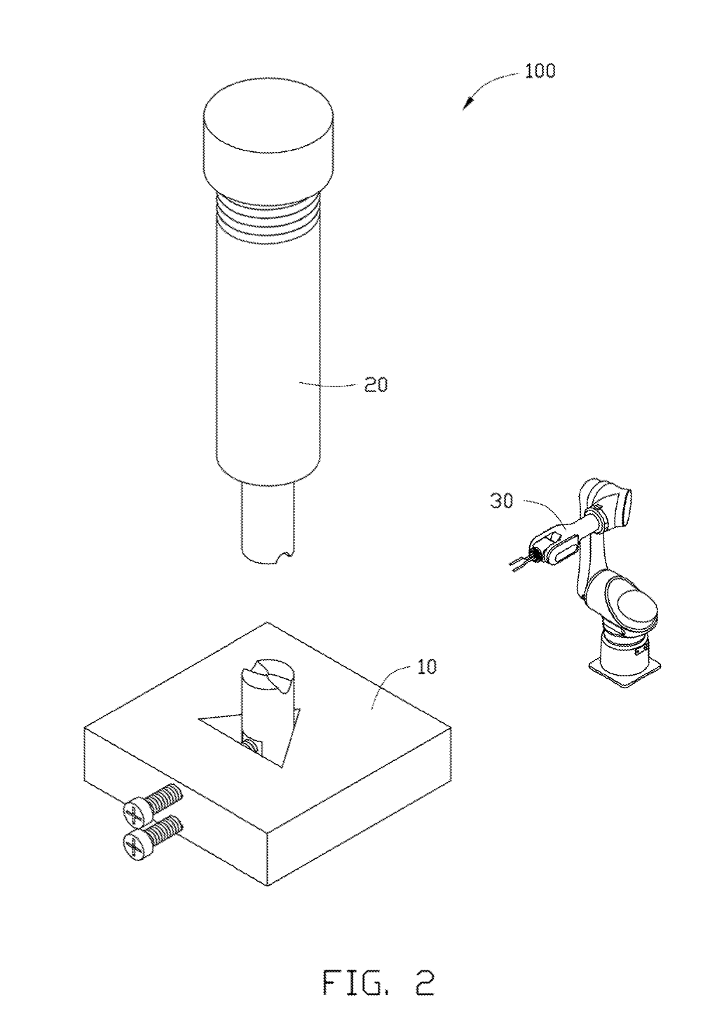

In step S2, referring to FIG. 2, the cutting apparatus 100 is configured to cutting the micro-grids 40 from the metal substrate 50. The cutting apparatus 100 includes a support 10, a cutting module 20 and a catching module 30. The support 10 is configured to support the metal substrate 50. The cutting module 20 is used to cutting the micro-grids 40 from the metal substrate 50.

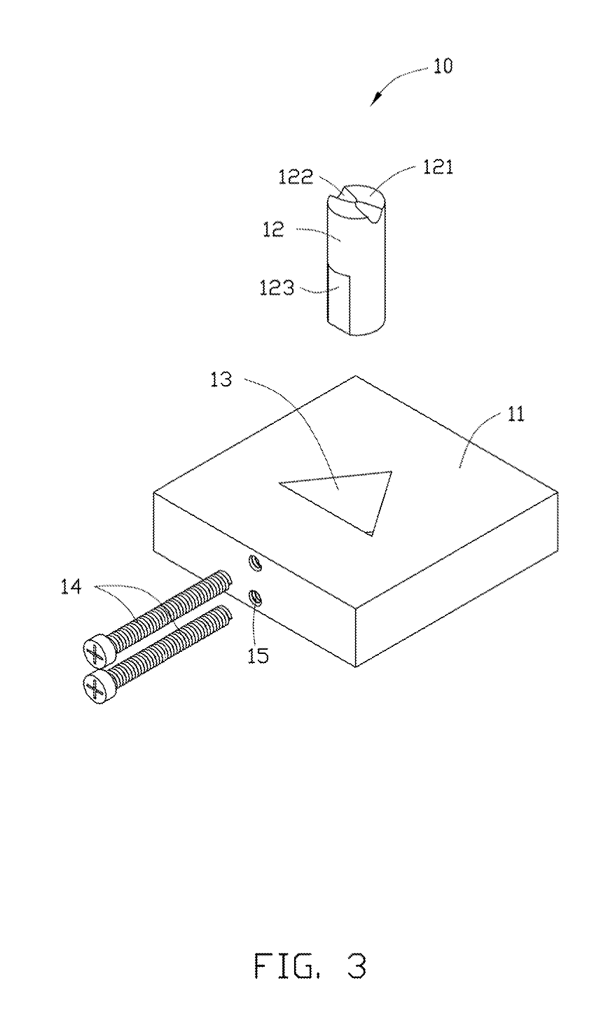

Referring to FIG. 3, the support 10 includes a bottom 11 and a cylindrical holder 12. The holder 12 can be fixed on the bottom 11 by mechanical method or adhesive. In one embodiment according to FIG. 3, the bottom 11 defines a through hole 13, the holder 12 is inserted to the through hole 13. The holder 12 defines a planar surface 123. The planar surface 123 contacts a side surface of the through hole 13, and the holder 12 is fixed on the bottom 11 via two screws 14. The two screws 14 are inserted into the bottom 11 through two screw threads 15.

The cylindrical holder 12 includes a supporting body 121 to support the micro-grids 40. The supporting body 121 has a round structure. A diameter of the supporting body 121 is greater than or equal to a diameter of each of the micro-grids 40. The supporting body 121 defines two grooves 122 at its top surface. The two grooves 122 are opposite with each other. A shape of the grooves 122 is not limited, it can be cylinder or square. In another embodiment, the supporting body 121 can define one square groove passing through the top surface thereof.

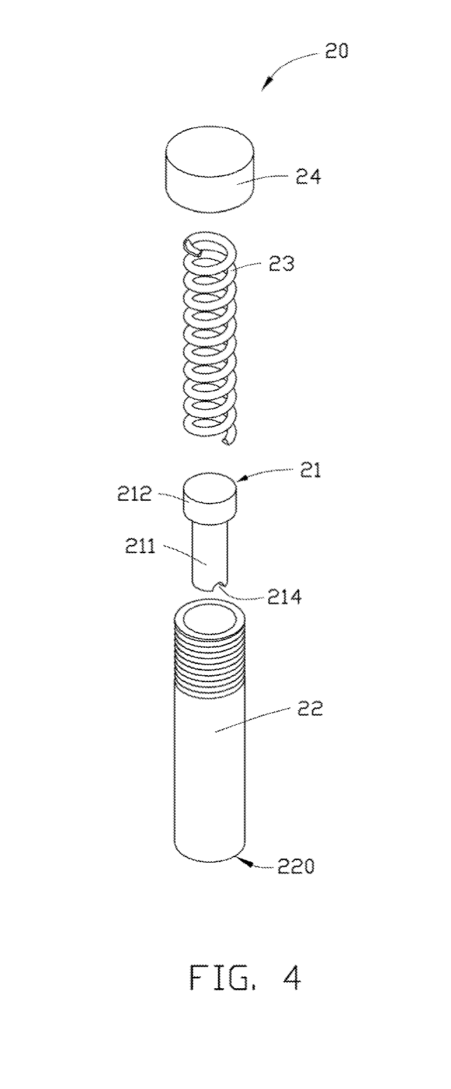

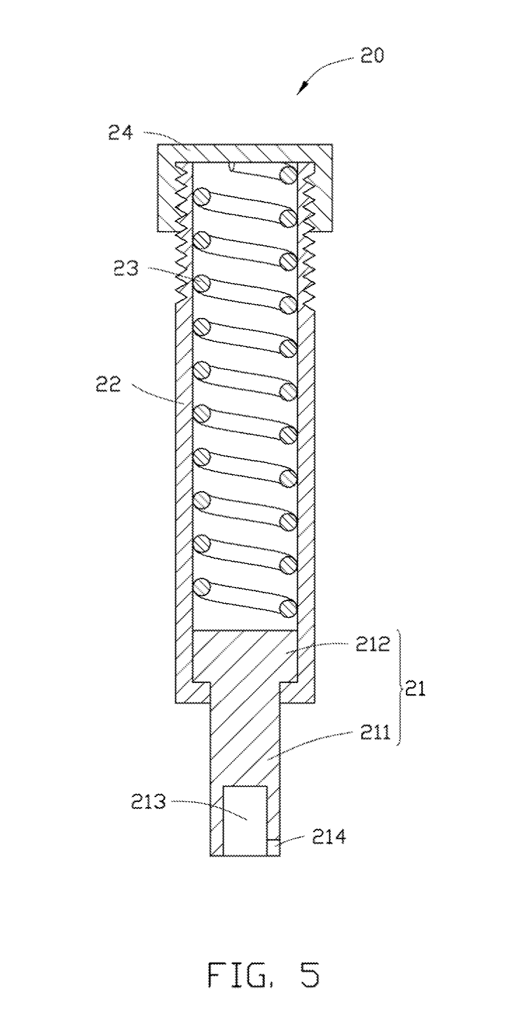

Referring to FIGS. 4 and 5, the cutting module 20 includes a fixing element 21, a cutting structure 22, a spring 23 and a screw nut 24. The fixing element 21 has a pin structure and includes a head 212 and a column 211 extending downwardly from the head 212. The column 211 and the head 212 are coaxial. A diameter of the column 211 is smaller than that of the head 212, and a step is defined by the combining surface of the column 211 and the head 212. The column 211 defines a cylindrical hole 213 at its free end. The cylindrical hole 213 and the head 212 are coaxial. A diameter of the cylindrical hole 213 is greater than the diameter of the grid structure 42 and smaller than or equal to a diameter of each of the micro-grids 40. A diameter of the column 211 is almost the same as the diameter of each of the micro-girds 40. A cutout 214 can be defined in the portion of the column 211 which defines the cylindrical hole 213. The cutout 214 is communicated with the cylindrical hole 213.

The cutting structure 22 has a tube structure defining an open 220 at one free end thereof. The cutting structure 22 defines a cylindrical through hole. A diameter of the open 220 is smaller than that of the through hole, whereby a step is formed at the open 220. The diameter of the through hole is matched with a diameter of the head 212. The diameter of the open 220 is matched with the column 211. The fixing element 21 can extend through the cutting structure 22 from the cylindrical through hole such that the head 212 of the fixing element 21 is kept by the open 220. The diameter of the open 220 is almost the same as that of the cylindrical holder 12. The diameter of the open 220 is a little greater than the diameter of each of the micro-grids 40. A screw thread is formed at one end of the cutting structure 22. The screw thread is engaged with the screw nut 24.

The fixing element 21 extends through the through hole of the cutting structure 22 such that the column 211 extends out of the cutting structure 22 from the open 220. The head 212 is kept by the open 220 of the cutting structure 22. The spring 23 is located in the through hole of the cutting structure 22. The screw nut 24 is engaged with the cutting structure 22 via the screw thread. One end of the spring 23 connects with the screw nut 24, the other end of the spring 23 connects with the fixing element 21. The fixing element 21 can move freely in the through hole of the cutting structure 22 via the spring 23.

The catching module 30 is used to catch each of the micro-grids 40 after it is separated from the metal substrate 50. The catching module 30 includes a clamp. The clamp can catch each of the micro-grids 40 through the cutout 214, and then move each of the micro-grids 40.

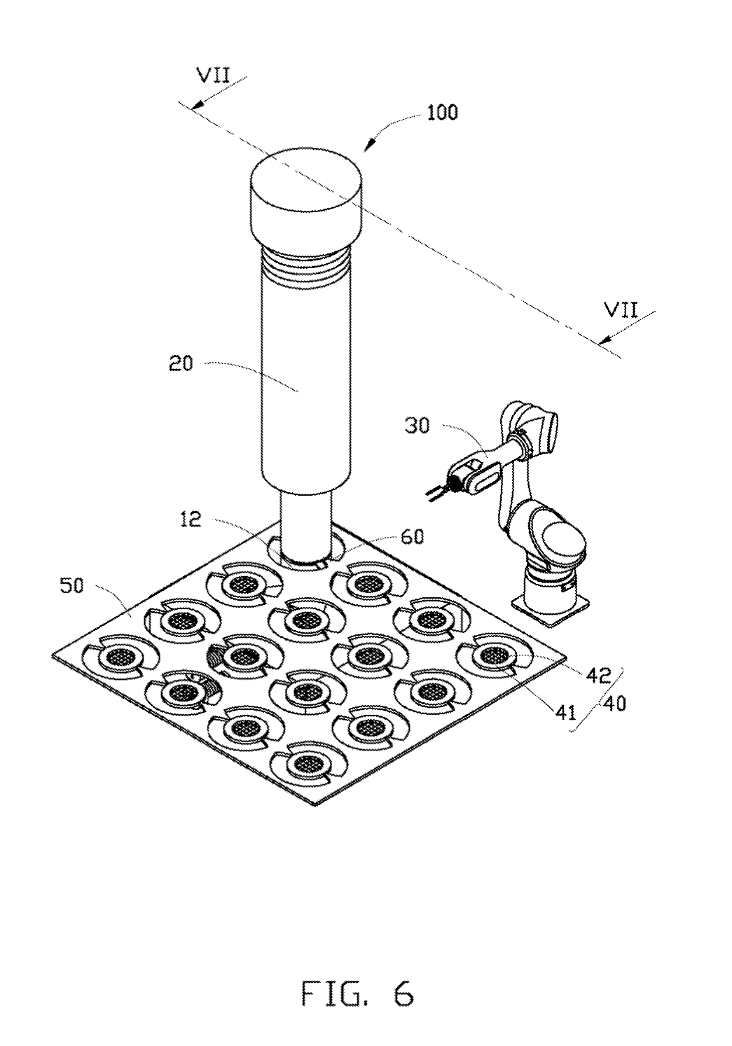

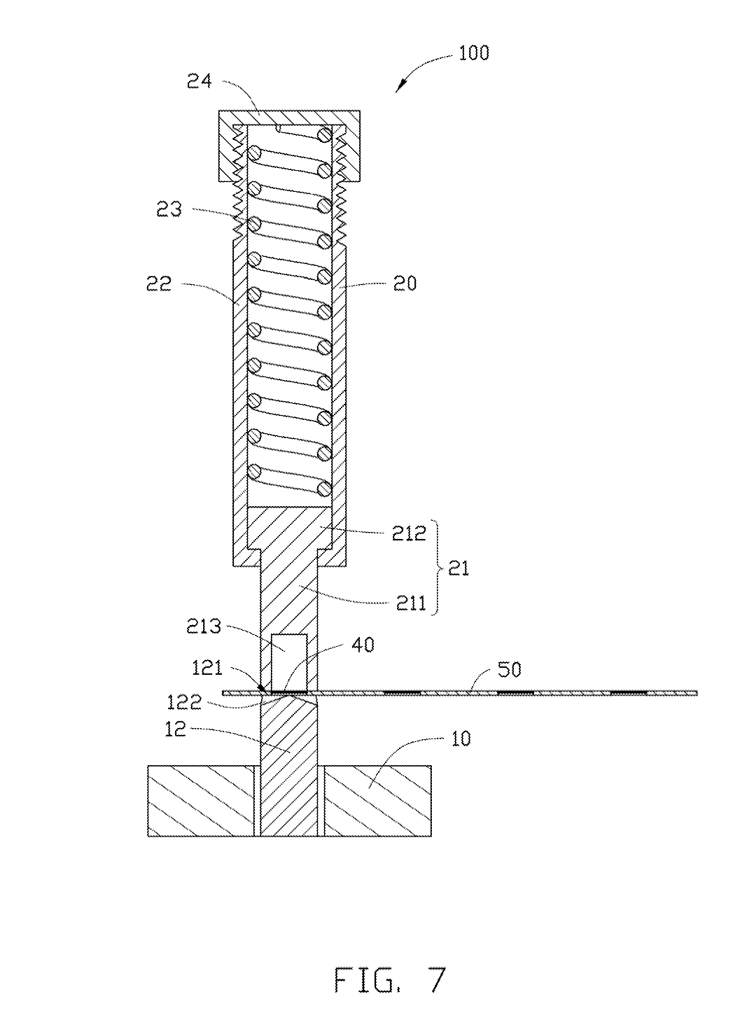

In step S3, referring to FIGS. 6 and 7, one of the micro-grids 40 is located on the top surface of the supporting body 121. The two connections 60 are separately hung above the grooves 122 on the top surface of the supporting body 121. The cutting module 20 is moved above the micro-grids 40, thereby the fixing element 21 is opposite to the micro-grids 40. The cylindrical hole 213 faces the grid structure 42 of each of the micro-grids 40, because the diameter of the cylindrical hole 213 is greater than that of the grid structure 42, the grid structure 42 is located in the cylindrical hole 213, in case that the grid structure 42 is destroyed by the cutting module 20. One of the micro-grids 40 is located between the fixing element 21 and the top surface of the supporting body 121, and is fixed on the supporting body 121 by the fixing element 21.

In step S4, the screw nut 24 is pressed down, the fixing element 21 shrinks into the through hole of the cutting structure 22, and the spring 23 makes the cutting structure 22 move towards one of the micro-grids 40. Then, the cutting structure 22 contacts the connections 60, and makes the connections 60 deform under a pressing force of the cutting structure 22. Then, the connections 60 are stretched by the pressing force, the point contact between each of the micro-grids 40 and each of the connections 60 is disconnected, and each of the micro-grids 40 is separated from the connections. Thus, each of the micro-grids 40 is cut down from the metal substrate 50. Because the connections 60 are suspended above the grooves 122, a cutting speed can be slowed by the grooves 122, in case that the micro-grids 40 are destroyed by a high speed.

In step S4, after each of the micro-grids 40 is separated from the metal substrate 50, the clamp can catch each of the micro-grids 40 through the cutout 214, and then move each of the micro-grids 40. The clamp catches the bridge ring 41 of the micro-grid, in case that the grid structure 42 is destroyed by the clamp. The micro-grids 40 can be put into a box.

The method for cutting micro-grids from a metal substrate can be easily operated. The cutting apparatus has a simple structure. When the cutting apparatus is used to cutting the micro-grids from the metal substrate, the micro-grids can be separated from the metal substrate easily without destroy the micro-grids.

Finally, it is to be understood that the above-described embodiments are intended to illustrate rather than limit the present disclosure. Variations may be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

Depending on the embodiment, certain of the steps of methods described may be removed, others may be added, and the sequence of steps may be altered. The description and the claims drawn to a method may include some indication in reference to certain steps. However, the indication used is only to be viewed for identification purposes and not as a suggestion as to an order for the steps.

What is claimed is:

1. A method for cutting micro-grids comprising steps of:
S1: making a metal substrate with a plurality of micro-grids on the metal substrate;
S2: making a cutting apparatus comprising a support, a cutting module, and a catching module;
S3: laying the metal substrate on the support, moving the cutting module above the support to make one of the plurality of micro-grids between the support and the cutting module; and
S4: pressing the cutting module down to the support to cut the micro-grid off the metal substrate, and catching the micro-grid with the catching module.

2. The method of claim 1, wherein in step S1, the metal substrate comprises a plurality of holes, each of the plurality of micro-grids is suspended in one hole and connected with the metal substrate via two connections.

3. The method of claim 2, wherein each of the two connections connects with the each of the plurality of micro-grids via a point contact, and with the metal substrate via a linear contact.

4. The method of claim 3, wherein each of the two connections has a triangular structure, a corner of each of the two connections is connected with each of the plurality of micro-grids, and a side of each of the two connections opposite to the corner is connected with the metal substrate.

5. The method of claim 1, wherein in step S2, the support comprises a bottom and a holder, and the holder is fixed on the bottom.

6. The method of claim 5, wherein the bottom defines a through hole, the holder is configured to be inserted to the through hole and fixed on the bottom via two screws.

7. The method of claim 5, wherein the holder comprises a supporting body configured to support the plurality of micro-grids, the supporting body is a cylindrical structure, a diameter of the supporting body is greater than or equal to a diameter of each of the plurality of micro-grids.

8. The method of claim 7, wherein two grooves are defined on a top surface of the cylindrical structure of the supporting body, the two grooves are opposite with each other.

9. The method of claim 7, wherein the supporting body defines one square groove passing through a top surface of the cylindrical structure of the supporting body.

10. The method of claim 1, wherein in the step S2, the cutting module comprises:
a fixing element comprising a column and a head connected with the column;
a cutting structure defining a through hole and an open, the head is located in the through hole, the column extends out of the open;
a spring located in the through hole of the cutting structure; and
a screw nut fixed on one end of the cutting structure.

11. The method of claim 10, wherein one end of the spring contacts with the screw nut, another end of the spring contacts with the fixing element.

12. The method of claim 11, wherein each of the plurality of micro-grids comprises a bridge ring and a grid structure, the gird structure is located in the bridge ring, the column defines a cylindrical hole, a diameter of the cylindrical hole is greater than a diameter of the grid structure and smaller than a diameter of each of the plurality of micro-grids.

13. The method of claim 12, wherein in step S3, the support comprises a supporting body defining a top surface, a micro-grid of the plurality of micro-grids is located on the top surface, the grid structure faces the cylindrical hole of the column.

14. The method of claim 13, wherein the micro-grid is located between the fixing element and the support and fixed on the supporting body by the fixing element.

15. The method of claim 13, wherein the metal substrate comprises a plurality of holes, each of the plurality of micro-grids is suspended in one of the plurality of holes and connected with the metal substrate via two connections, two grooves are defined on the top surface, the two connections are separately hung above the two grooves on the supporting surface.

16. The method of claim 15, wherein in step S4, the screw nut is pressed down, the fixing element shrinks into the through hole of the cutting structure, and the spring moves the cutting structure toward the micro-grid.

17. The method of claim 16, wherein the cutting structure contacts the two connections and stretches the two connections under a pressing force of the cutting structure so that the micro-grid and each of the two connections are disconnected.

18. The method of claim 1, further comprising a step S5, wherein step S5 comprises repeating steps S3 and S4 until a desired number of the plurality of micro-grids are obtained.

19. A method for cutting micro-grids comprising steps of:
making a metal substrate with a plurality of micro-grids formed on the metal substrate and a cutting apparatus comprising a support and a cutting module, each of the plurality of micro-girds is connected with the metal substrate by two connections;
laying the metal substrate on the support, moving the cutting module above the support to make one of the plurality of micro-grids be located between the support and the cutting module; and
pressing the cutting module towards the support to cut the micro-grid from the metal substrate, and separating the micro-grid from the two connections.

20. The method of claim 19, wherein the micro-grid is separate from the two connections by stretching the two connections by the cutting module.
